(19) United States
(12) Patent Application Publication
(10) Pub. No.: US 2012/0191392 A1
(43) Pub. Date: Jul. 26, 2012

(54) METHOD FOR ANALYZING CORRELATIONS AMONG DEVICE ELECTRICAL CHARACTERISTICS AND METHOD FOR OPTIMIZING DEVICE STRUCTURE

(75) Inventors: Qingqing Liang, Lagrangeville, NY (US); Huilong Zhu, Poughkeepsie, NY (US); Huicai Zhong, San Jose, CA (US)

(73) Assignee: Institute of Microelectronics Chinese Academy of Science, Beijing (CN)

(21) Appl. No.: 13/321,684

(22) PCT Filed: Aug. 10, 2011
(86) PCT No.: PCT/CN11/78204

§ 371 Date: Nov. 21, 2011

(30) Foreign Application Priority Data
Jan. 20, 2011 (CN) 201110023167.6

(51) Int. Cl. G06F 19/00; G01R 27/00; G01R 19/00

(52) U.S. Cl. 702/65; 702/57; 702/64

(57) ABSTRACT

A method for analyzing correlations among electrical characteristics of an electronic device and a method for optimizing a structure of the electronic device are disclosed. The electronic device may comprises a plurality of electrical characteristics v1, v2, v3, . . . , vm, wherein the electrical characteristics v2, v3, . . . . , vm constitute a (m−1) dimensional space. For a plurality of discrete measurement points (v2k, v3k, . . . , vmk) in the (m−1) dimensional space, a plurality of corresponding measurement values of the electrical characteristic v1 has already been obtained. The method comprises: performing a Delaunay triangulation operation on the plurality of measurement points (v2k, v3k, . . . , vmk) in the (m−1) dimensional space; calculating a plurality of interpolation values of the electrical characteristic v1 corresponding to a plurality of interpolation points (v2i, v3i, . . . , vmi) by means of interpolation based on the result of the Delaunay triangulation operation; and determining the correlation between the electrical characteristics v1 and v2 from the plurality of measurement points and the plurality of interpolation points as well as the plurality of corresponding measurement values and the plurality of corresponding interpolation values.

### CROSS-REFERENCE TO RELATED APPLICATION(S)

The present application claims priority to Chinese Application No. 201110023167.6, filed on Jan. 20, 2011, entitled “method for analyzing correlations among device electrical characteristics and method for optimizing device structure”, the entire disclosure of which is incorporated herein by reference.

### TECHNICAL FIELD

The present disclosure relates to the field of electronic devices, and more particularly, to a method for analyzing correlations among electrical characteristics of an electronic device and a method for optimizing a structure of the electronic device.

### BACKGROUND

For most electronic devices such as Integrated Circuit (IC) devices, especially, Large Scale Integrated Circuit (LSIC) devices, there are various electrical characteristics (e.g., current characteristic, voltage characteristic and the like). To extract correlations among the various electrical characteristics is a basis for characterizing an entire system such as an IC device.

The already known Principal Components Analysis (PCA) method is directed to linear systems, and cannot be applied to non-linear systems. However, for most electronic devices such as IC devices, various variables (electrical characteristics) therein are non-linear ones and have strong dependencies on each other. As a result, it is necessary to adopt data screening methods to extract a trend of influences of every two variables on each other (that is, variations of the two variables subjected to the extraction operation caused by other variables are reduced by the screening). However, the conventional screening methods cannot precisely extract the trend from limited samples.

In view of the above, there is a need for a method for analyzing a trend of influences of every two electrical characteristics on each other in an electronic device, so as to precisely characterize the non-linear system of the electronic device and thus to improve design and manufacture of the device.

### SUMMARY

An object of the present disclosure is to provide a method for analyzing correlations among electrical characteristics of an electronic device.

According to an embodiment, there is provided a method for analyzing correlations among electrical characteristics of an electronic device. The electronic device may comprise a plurality of electrical characteristics v1, v2, v3, . . . , vm, where m is an integer greater than 1. The electrical characteristics v2, v3, . . . , vm constitute a (m−1) dimensional space, and (v2i, v3i, . . . , vmi) is a point in the (m−1) dimensional space. For a plurality of discrete measurement points (v2k, v3k, . . . , vmk) in the (m−1) dimensional space, a plurality of corresponding measurement values of the electrical characteristic v1 has already been obtained, where i and k are indices of the points. The method may comprise: performing a Delaunay triangulation operation on the plurality of measurement points (v2k, v3k, . . . , vmk) in the (m−1) dimensional space; calculating a plurality of interpolation values of the electrical characteristic v1 corresponding to a plurality of interpolation points (v2i, v3i, . . . , vmi) by means of interpolation based on the result of the Delaunay triangulation operation; and determining the correlation between the electrical characteristics v1 and v2 from the plurality of measurement points and the plurality of interpolation points as well as the plurality of corresponding measurement values and the plurality of corresponding interpolation values.

Therefore, the limited measurement samples can be expanded by means of interpolation, and thus it is possible to more precisely extract correlations among the electrical characteristics from the expanded data.

According to a further embodiment, the interpolation may comprise: calculating an interpolation value corresponding to an interpolation point by means of interpolation using measurement values corresponding to measurement points at vertices of a Delaunay triangulation cell, within which the interpolation point is located, wherein the Delaunay triangulation cell is derived from the Delaunay triangulation operation.

According to the embodiment, the interpolation can be effectively performed by the Delaunay triangulation method.

For example, the Delaunay triangulation cell is a triangle when m=3, and is a tetrahedron when m=4.

According to a further embodiment, determining the correlation between the electrical characteristics v1 and v2 may comprise: selecting points of (v2i, v3i=C3, v4i=C4, . . . , vmi=Cm) as well as their corresponding values of the electrical characteristic v1 with respect to the plurality of measurement points and the plurality of interpolation points, to determine the correlation between v1 and v2, wherein C3, C4, . . . , Cm are constants.

According to the embodiment, influences caused by fluctuations of v3, v4, . . . , vm on the variations of v1/v2 can be removed by fixing them.

According to a further embodiment, each of the plurality of interpolation points can be a point of (v2i, v3i=C3, v4i=C4, . . . , vmi=Cm).

According to a further embodiment, the plurality of electrical characteristics v1, v2, v3, . . . , vm are selected so that v3, . . . , vm are substantially independent of a physical structural feature sk of the electronic device, and wherein the determined correlation between the electrical characteristics v1 and v2 represents the physical structural feature sk.

In this way, the influences of the single physical structural feature sk on the device electrical characteristics can be determined. As a result, it is possible to determine whether the physical structural feature sk is set appropriately or not.

According to a further embodiment, the electronic device may comprise an integrated circuit device. In such a case, the electrical characteristics may comprise saturation-region current, linear-region current, channel inversion capacitance, channel-source/drain overlap capacitance, sub-threshold slope, and/or threshold voltage, and the physical structural feature may comprise gate length, gate dielectric thickness, mobility and/or parasitic capacitance.

According to a further embodiment, there is provided a method for optimizing a structure of an electronic device, comprising: determining the correlation between the electrical characteristics v1 and v2 by the above method, wherein the correlation represents the physical structural feature sk; and selecting an appropriate value for the physical structural feature sk to optimize the electronic device.

### BRIEF DESCRIPTION OF THE DRAWINGS

The above and other objects, features, and advantages of the present disclosure will become apparent from the following descriptions on embodiments of the present invention with reference to the drawings, in which:

FIG. 1 is a schematic flowchart showing a method for analyzing correlations among electrical characteristics of a device according to an embodiment;

FIG. 2 is a schematic flowchart showing expansion of data samples according to an embodiment;

FIG. 3 is an example showing Delaunay triangulation according to an embodiment; and

FIG. 4 is an example showing analysis of dependencies between electrical characteristics of a CMOS device according to an embodiment.

### DETAILED DESCRIPTION

Hereinafter, detailed descriptions are given with reference to embodiments shown in the attached drawings. However, it is to be understood that those descriptions are just provided for illustrative purpose, rather than limiting the present disclosure. Further, in the following, descriptions of known structures and techniques are omitted so as not to unnecessarily obscure the present disclosure.

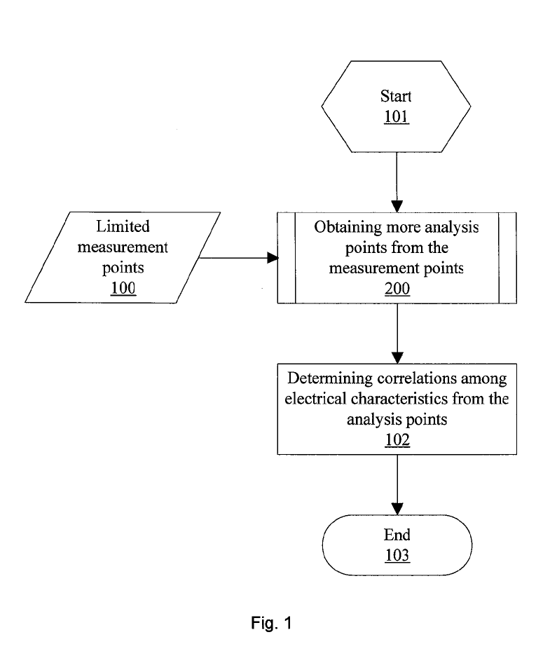

FIG. 1 is a schematic flowchart showing a method for analyzing correlations among electrical characteristics of a device according to an embodiment.

As shown in FIG. 1, the method starts at block 101. Here, assume that the electronic device to be analyzed comprises a plurality of electrical characteristics v1, v2, v3, . . . , vm, where m is an integer greater than 1. For example, those electrical characteristics may be voltage/current characteristics and the like exhibited by the device to the outside, and may comprise, but not limited to, a drive current, a leakage current, a threshold voltage etc. It is to be noted that the electronic device may comprise other electrical characteristics. Those electrical characteristics can be obtained by electrical tests on a finished device, or by simulations of a device model.

At least some of the electrical characteristics v1, v2, v3, . . . , vm have dependencies on each other. Here, assume that the correlation between v1 and v2 is to be analyzed, that is

v1=f(v2, v3, . . . , vm).

That is to say, variables v3, . . . , vm are at least part of the electrical characteristics of this system (i.e., the analyzed electronic device) which influence the correlation between v1 and v2. Here, the correlation is denoted by f( . . . ). F( . . . ) may be a function that cannot be analytically expressed.

Here, the variables v2, v3, . . . , vm may be considered as respective dimensions of a (m−1) dimensional space, so that (v2i, v3i, . . . , vmi) becomes a “point” in this (m−1) dimensional space. Accordingly, v1i=f(v2i, v3i, . . . , vmi) is a function value at this “point”.

Hereinafter, the following definitions are used for ease of description.

| | |
|---|---|
| (m−1) dimensional | a space whose respective dimensions are constituted |
| space | by the variables v2, v3, . . . , vm (the electronic |
| | characteristics) |
| (discrete) point | a point (v2i, v3i, . . . , vmi) in the (m−1) |
| | dimensional space |
| function value at | the value of a parameter (e.g. v1i) corresponding |
| a discrete point | to the point (v2i, v3i, . . . , vmi) |
| measurement | a combination of variables, [(v2k, v3k, . . . , |
| sample | vmk), v1k], which is obtained by means of |
| | measurements or circuit tests |
| supplementary | a combination of variables, [(v2i, v3i, . . . , |
| sample | vmi), v1i], which is obtained by interpolation |
| | based on the measurement samples |
| analysis samples | a combination of measurement samples and |
| | supplementary samples |
| measurement point | a point in the (m−1) dimensional space corre- |
| | sponding to a measurement sample [(v2k, v3k, . . . , |
| | vmk), v1k], that is, a point (v2k, v3k, . . . , |
| | vmk) whose function value v1k is already measured |
| interpolation | a point in the (m−1) dimensional space corre- |
| point | sponding to a supplementary sample [(v2i, v3i, . . . , |
| | vmi), v1i], that is, a point (v2i, v3i, . . . , |
| | vmi) whose function value v1i is obtained by |
| | interpolation |
| analysis points | a combination of measurement points and |
| | interpolation points |

Notes:
in “[xi, yi]”, “xi” denotes a discrete point in the (m−1) dimensional space, that is, (v2i, v3i, . . . , vmi), and “yi” denotes the function value corresponding to this point, that is, v1i, wherein i and k are indices of the points and the corresponding function values.

To analyze the correlation between v1 and v2, a set of data samples is desired. Here, as shown in block 100 in FIG. 1, for a limited number of measurement points (v2k, v3k, . . . , vmk), their corresponding function values v1k are obtained. In other words, measurement samples [(v2k, v3k, . . . , vmk), v1k] are obtained in advance. For example, those measurement samples may be obtained by circuit tests or circuit simulations.

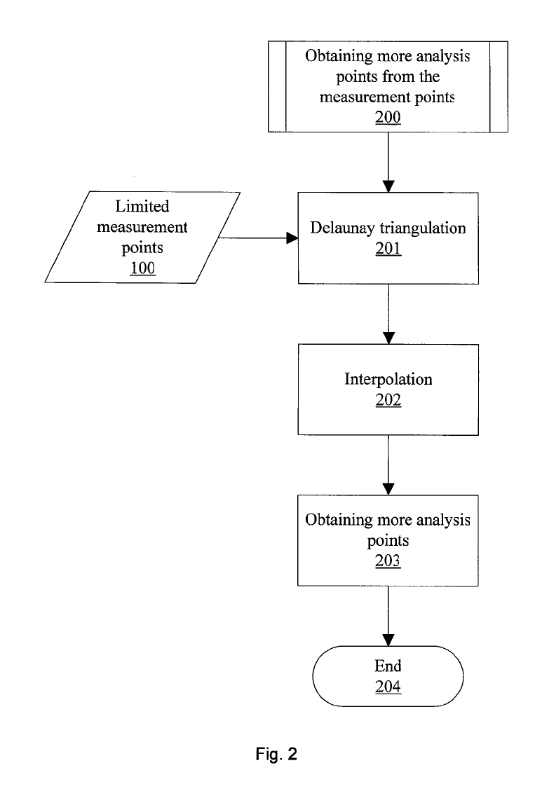

However, as stated in the background portion, it is difficult to precisely analyze the correlation between v1 and v2 from the limited measurement samples. For this reason, it may be desirable to expand the measurement samples. For example, more supplementary samples can be obtained from the measurement samples by means of interpolation. As a result, it is possible to analyze the correlation between v1 and v2 based on an increased number of analysis samples (including the measurement samples and the supplementary samples). The obtaining of the analysis samples is achieved in block 200, which, will be described in detail with reference to FIG. 2.

According to an embodiment, measurement samples used to calculate a supplementary sample are selected based on a Delaunay triangulation method.

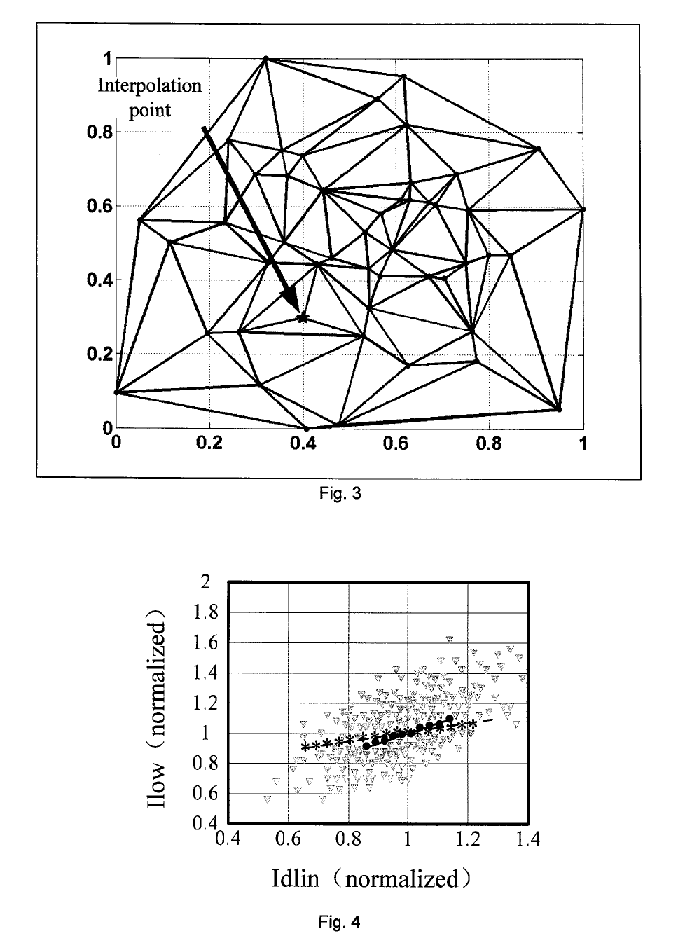

Specifically, as shown in FIG. 2, in sub-block 201, a Delaunay triangulation operation is performed on the measurement points (v2k, v3k, . . . , vmk) in the (m−1) dimensional space. FIG. 3 is an example showing the Delaunay triangulation operation in a 2 dimensional space (that is, m=3), wherein the horizontal axis represents a normalized v2, and the vertical axis represents a normalized v3 (or alternatively, the horizontal axis represents the normalized v3, and the vertical axis represents the normalized v2). Respective triangles shown in FIG. 3 are Delaunay triangulation cells (a triangle in a 2 dimensional space, a tetrahedron in a 3 dimensional space, and so on) as a result of the Delaynay triangulation operation, and their vertices correspond to the respective measurement points. The Delaunay triangulation operation per se is well known to those skilled in the art, by which it is possible to divide a multidimensional space into some discrete cells having the measurement points as vertices. Here, detailed descriptions of the Delaunay triangulation operation are omitted.

Then, in sub-block 202, measurement points at vertices of a Delaunay triangulation cell, within which an interpolation point is located, are selected for interpolation of the interpolation point. For example, in the example shown in FIG. 3, for an interpolation point indicated by the arrow, its corresponding v1i value can be calculated by using v1k values at three vertices of a Delaunay triangle within which the interpolation point is located.

Next, in sub-block 203, the increased number of analysis points is obtained by combining the measurement points and the interpolation points, to more precisely analyze the correlation between v1 and v2.

Finally, the process of block 200 is ended at sub-block 204.

After the increased number of analysis points is obtained in block 200, the correlation between v1 and v2 can be analyzed based on those analysis points (as well as their corresponding v1i values) in block 102.

Specifically, to analyze the correlation between the characteristics v1 and v2, it is desirable to remove influences caused by the remaining characteristics v3, vm. For example, those variables may be fixed, so that v3i=C3, v4i=C4, . . . , vmi=Cm, where C3, C4, . . . , Cm are constants. In this way, the correlation between v1 and v2 can be determined as v1=f (v2, C3, . . . Cm).

To do this, points of (v2i, v3i=C3, v4i=C4, . . . , vmi=Cm) (as well as their corresponding v1i values) can be selected from the analysis points. According to an embodiment, the interpolation points each can be selected as points of (v2i, v3i=C3, v4i=C4, . . . , vmi=Cm).

Finally, the method is ended at block 103.

The above described correlations analyzing method has a particularly advantageous application. It is known to those skilled in the art that electrical characteristics such as v1, v2, v3, vm exhibited by an electronic device to the outside are determined by physical structural features (which are denoted by s1, s2, . . . , sn, where n is an integer greater than 1) of the electronic device itself. That is to say, an electrical characteristic vi (i=1, . . . , m) can be expressed as vi=g(s1, s2, . . . , sn), where g( . . . ) represents the correlations of the electrical characteristic vi on the physical structural features s1, s2, . . . , sn. G( . . . ) may be a function that cannot be analytically expressed.

For example, in a case where the electronic device is an IC device, the electrical characteristics such as v1, v2, V3, . . . , vm may comprise a saturation region current (Ilow), a linear region current (Idin), a channel inversion capacitance (Cinv), a channel-source/drain overlap capacitance (Cov), a sub-threshold slope (SS), a leakage current (Ioff), a threshold voltage (Vtlin), and the like. The physical structural features s1, s2, . . . , sn of the IC device may comprise a gate length (Lgate), a gate dielectric thickness (Tox), a mobility (Mob), a parasitic resistance (Rpar), and the like.

According to the correlations analyzing method described above, it is possible to determine influences of a single physical structural feature sk (k=1, . . . , n) on the electrical characteristics of the device, which will be described in detail in the following.

For example, the electrical characteristics v3, v4, . . . , vm can be selected so that they are substantially independent of a single physical structural feature sk of the device. Thus, the correlation between v1 and v2 obtained by the above correlations analyzing method can embody the influences of the signal physical structural feature sk on the electrical characteristics of the device, while influences from the remaining physical structural features s1, . . . , sk−1, sk+1, . . . , sn are removed. As a result, it is possible to determine whether the physical structural feature sk is set appropriately or not.

For example, in a case of an IC device, when a sample device is manufactured according to a certain design (defining specific physical structural features such as gate length, gate dielectric thickness, mobility, and parasitic resistance), the sample device can be subjected to electrical tests to determine whether the actual electrical characteristics of this device satisfy requirements or not, and thus to determine whether the design is appropriate or not. Through the electrical tests, sets of values, for example, [(v2k, v3k, . . . , vmk), v1k] as described above, of the electrical characteristics can be obtained.

Those measured values of the electrical characteristics can be expanded by the above described interpolation method, in order to more precisely analyze the correlations among the electrical characteristics. In analyzing the correlations, the electrical characteristics v3, v4, . . . , vm can be selected as described above so that they are substantially independent of a physical structural feature sk, for example. As a result, the influences of the single physical structural feature sk on the electrical characteristics can be determined, and thus it is possible to determine whether the physical structural feature sk is appropriately set in the design or not and to modify the design accordingly.

For example, in a case of a CMOS device, it is possible to set v1=Ilow, v2=Idlin, v3=Cinv, v4=Coy, and v5=SS (that is, m=5). Since the influences of the mobility (Mob) on Cinv, Cov, and SS are neglectable, Cinv, Coy, and SS are substantially independent of Mob. Thus, the function Ilow=f(Idlin, Cinv=C3, Cov=C4, SS=C5) obtained by the above analyzing method is immune to fluctuations of Cinv, Coy, and SS, and the trend of Ilow versus Idlin is substantially determined by the mobility Mob. That is to say, the influences of the physical structural feature Mob on the electrical characteristics are extracted individually.

Similarly, it is possible to set v1=Ilow, v2=Idlin, v3=Cinv, v4=Ioff, and v5=Vtlin (that is, m=5). Since the influences of the parasitic resistance (Rpar) on Cinv, Ioff, and Vtlin are neglectable, Cinv, Ioff, and Vtlin are substantially independent of Rpar. Thus, the function Ilow=f(Idlin, Cinv=C3, Ioff=C4, Vtlin=C5) obtained by the above analyzing method is immune to fluctuations of Cinv, Ioff, and Vtlin, and the trend of Ilow versus Idlin is substantially determined by the parasitic resistance Rpar. That is to say, the influences of the physical structural feature Rpar on the electrical characteristics are extracted individually.

Likewise, the influences of other single physical structural feature (such as extension and halo) on the device electrical characteristics can be extracted individually.

FIG. 4 shows extracted dependencies between source-drain currents of a CMOS device (that is, the saturation region current Ilow and the linear region current Idlin) under different gate-source and drain-source biases, from which influences of other electrical characteristics are removed. The horizontal axis and the vertical axis represent Idlin and Ilow normalized with respect to respective statistical mean values, respectively. Specifically, points therein show a function of Ilow=f(Idlin, Cinv=C3, Coy=C4, SS=C5) extracted from measurement data (shown by gray triangles in the figure) according to the disclosed method, and marks of “*” show a function of Ilow=f(Idlin, Cinv=C3, Ioff=C4, Vtlin=C5) extracted from measurement data (not shown) according to the disclosed method.

As described above, the function Ilow=f(Idlin, Cinv=C3, Cov=C4, SS=C5) is substantially determined by the mobility Mob. FIG. 4 also shows a solid line representing the influence of the mobility on Ilow/Idlin obtained through theory/simulation analyses. It is found that the solid line substantially coincides with the correlations extracted according to the disclosed method. That is, the disclosed method indeed individually extracts the influence of the physical structural feature Mob on the device electrical characteristics.

Likewise, as described above, the function Ilow=f(Idlin, Cinv=C3, Ioff=C4, Vtlin=C5) is substantially determined by the parasitic resistance Rpar. FIG. 4 also shows a dashed line representing the influence of the parasitic resistance on Ilow/Idlin obtained through theory/simulation analyses. It is found that the dashed line substantially coincides with the correlations extracted according to the disclosed method. That is, the disclosed method indeed individually extracts the influence of the physical structural feature Rpar on the device electrical characteristics.

After the influences of the physical structural features such as Mob and Rpar on the device electrical characteristics are extracted as described above, it is possible to determine whether they are appropriate or not and to modify the design accordingly.

Although the above descriptions are given by an example of IC devices, the present disclosure is not limited thereto. Those skilled in the art will understand that the present disclosure is applicable to various multi-port (multi-variable) systems.

From the foregoing, it will be appreciated that specific embodiments of the disclosure have been described herein for purposes of illustration instead of limitation, but that various modifications may be made without deviating from the disclosure. Accordingly, the technology is not limited except as by the appended claims.

I/We claim:

1. A method for analyzing correlations among electrical characteristics of an electronic device, the electronic device comprising a plurality of electrical characteristics v1, v2, v3, . . . , vm, where m is an integer greater than 1, the electrical characteristics v2, v3, . . . , vm constituting a (m−1) dimensional space, (v2i, v3i, . . . , vmi) being a point in the (m−1) dimensional space, wherein for a plurality of discrete measurement points (v2k, v3k, . . . , vmk) in the (m−1) dimensional space, a plurality of corresponding measurement values of the electrical characteristic v1 has already been obtained, where i and k are indices of the points, the method comprising:
performing a Delaunay triangulation operation on the plurality of measurement points (v2k, v3k, . . . , vmk) in the (m−1) dimensional space;
calculating a plurality of interpolation values of the electrical characteristic v1 corresponding to a plurality of interpolation points (v2i, v3i, . . . , vmi) by means of interpolation based on the result of the Delaunay triangulation operation; and
determining the correlation between the electrical characteristics v1 and v2 from the plurality of measurement points and the plurality of interpolation points as well as the plurality of corresponding measurement values and the plurality of corresponding interpolation values.

2. The method according to claim 1, wherein the interpolation comprises:
calculating an interpolation value corresponding to an interpolation point by means of interpolation using measurement values corresponding to measurement points at vertices of a Delaunay triangulation cell within which the interpolation point is located, wherein the Delaunay triangulation cell is derived from the Delaunay triangulation operation.

3. The method according to claim 2, wherein the Delaunay triangulation cell is a triangle when m=3, and is a tetrahedron when m=4.

4. The method according to claim 1, wherein determining the correlation between the electrical characteristics v1 and v2 comprises:
selecting points of (v2i, v3i=C3, v4i=C4, . . . , vmi=Cm) as well as their corresponding values of the electrical characteristic v1 with respect to the plurality of measurement points and the plurality of interpolation points, to determine the correlation between v1 and v2, wherein C3, C4, . . . , Cm are constants.

5. The method according to claim 4, wherein each of the plurality of interpolation points is a point of (v2i, v3i=C3, v4i=C4, . . . , vmi=Cm).

6. The method according to claim 1, wherein the plurality of electrical characteristics v1, v2, v3, . . . , vm are selected so that v3, . . . , vm are substantially independent of a physical structural feature sk of the electronic device, and wherein the determined correlation between the electrical characteristics v1 and v2 represents the physical structural feature sk.

7. The method according to claim 6, wherein the electronic device comprises an integrated circuit device, and wherein
the electrical characteristics comprises saturation-region current, linear-region current, channel inversion capacitance, channel-source/drain overlap capacitance, sub-threshold slope, and/or threshold voltage, and
the physical structural feature comprises gate length, gate dielectric thickness, mobility and/or parasitic capacitance.

8. A method for optimizing a structure of an electronic device, comprising:
determining the correlation between the electrical characteristics v1 and v2 by the method according to claim 6, wherein the correlation represents the physical structural feature sk; and
selecting an appropriate value for the physical structural feature sk to optimize the electronic device.
